(19) United States
(12) Patent Application Publication
(10) Pub. No.: US 2026/0253847 A1
(43) Pub. Date: Aug. 27, 2026

(54) SUBSTRATE PROCESSING APPARATUS, PLASMA GENERATING DEVICE, METHOD OF PROCESSING SUBSTRATE, METHOD OF MANUFACTURING SEMICONDUCTOR DEVICE AND RECORDING MEDIUM

(71) Applicant: Kokusai Electric Corporation, Tokyo (JP)

(72) Inventors: Yukinori ABURATANI, Toyama-shi, Toyama (JP); Iichiro TSUCHIKURA, Toyama-shi (JP); Tomoki TSUCHIYA, Toyama-shi (JP); Tsuyoshi TAKEDA, Toyama-shi (JP)

(73) Assignee: Kokusai Electric Corporation, Tokyo (JP)

(21) Appl. No.: 19/649,929

(22) Filed: Apr. 16, 2026

Related U.S. Application Data
(63) Continuation of application No. PCT/JP2024/012505, filed on Mar. 27, 2024.

(51) Int. Cl. H01J 37/32

(52) U.S. Cl. CPC H01J 37/32568; H01J 37/32091; H01J 37/32541

(57) ABSTRACT

Provided is a substrate processing technique that improves processing uniformity. The technique includes a process chamber configured to process a substrate, and a first electrode unit. The first electrode unit includes: a first electrode portion having a first electrode, to which high-frequency power is applied, and one second electrode, to which a reference potential is applied, the first and second electrodes of the first electrode portion having equal lengths; a second electrode portion having one first electrode and one second electrode whose lengths differ from those of the first and second electrodes of the first electrode portion; and a third electrode portion having one first electrode and one second electrode whose lengths differ from those of the electrodes in both the first electrode portion and the second electrode portion.

### DESCRIPTION

### CROSS-REFERENCE TO RELATED APPLICATION

This application is a Bypass Continuation Application of PCT International Application No. PCT/JP2024/012505, filed on March 27, 2024, the entire contents of which are incorporated herein by reference.

### BACKGROUND

### Field

The present disclosure relates to a substrate processing apparatus, a plasma generating device, a method of processing a substrate, a method of manufacturing a semiconductor device, and a recording medium.

### Description of the Related Art

As one step of a process of manufacturing a semiconductor device (device), substrate processing may be performed in which a substrate is carried in a process chamber of a substrate processing apparatus, and source gas and reactant gas are supplied into the process chamber to form various films such as an insulating film, a semiconductor film, and a conductor film on the substrate or to remove the various films.

In a mass production device in which a fine pattern is formed, in some cases, temperature lowering is required in order to suppress diffusion of impurities and to enable use of a material having low heat resistance, such as an organic material.

### SUMMARY

In order to solve such a problem, substrate processing is generally performed using plasma, but in some cases, it is difficult to perform uniform processing of a film.

The present disclosure provides a technique capable of more uniform substrate processing.

According to one aspect of the present disclosure, there is provided a technique that includes: a process chamber that processes a substrate; and a first electrode unit including: a first electrode portion including one of a plurality of first electrodes to which high frequency power is applied and one of a plurality of second electrodes to which a reference potential is applied, the one of the plurality of first electrodes and the one of the plurality of second electrodes included in the first electrode portion having equal lengths; a second electrode portion including one of the plurality of first electrodes and one of the plurality of second electrodes, the one of the plurality of first electrodes and the one of the plurality of second electrodes included in the second electrode portion having different lengths from those of the one of the plurality of first electrodes and the one of the plurality of second electrodes included in the first electrode portion; and a third electrode portion including one of the plurality of first electrodes and one of the plurality of second electrodes, the one of the plurality of first electrodes and the one of the plurality of second electrodes included in the third electrode portion having different lengths from those of the one of the plurality of first electrodes and the one of the plurality of second electrodes included in the first electrode portion and the one of the plurality of first electrodes and the one of the plurality of second electrodes included in the second electrode portion.

### BRIEF DESCRIPTION OF THE DRAWINGS

FIG. 1 is a schematic configuration diagram of a vertical processing furnace of a substrate processing apparatus preferably used in an embodiment of the present disclosure, and illustrates a processing furnace portion in a vertical cross section.

FIG. 2 is a cross-sectional view taken along line A-A in the substrate processing apparatus illustrated in FIG. 1.

FIG. 3A is a perspective diagram when an electrode in an embodiment of the present disclosure is installed on an electrode fixture, and FIG. 3B is a diagram for illustrating a positional relationship among a heater, the electrode fixture, an electrode, a protrusion for fixing the electrode, and a reaction tube in the embodiment of the present disclosure.

FIG. 4A is a front diagram of an electrode in an embodiment of the present disclosure, and FIG. 4B is a diagram for explaining a point of fixing the electrode to an electrode fixture.

FIG. 5 is a diagram for explaining a height of an electrode portion of an electrode unit in the embodiment of the present disclosure.

FIG. 6 is a schematic configuration diagram of a controller in the substrate processing apparatus illustrated in FIG. 1, and is a block diagram illustrating an example of a control system of the controller.

FIG. 7 is a flowchart illustrating an example of a substrate processing process using the substrate processing apparatus illustrated in FIG. 1.

FIG. 8 is a diagram for explaining a height of an electrode portion of an electrode unit in a modified example 1 of the present disclosure.

FIG. 9 is a diagram for explaining a height of an electrode portion of an electrode unit in a modified example 2 of the present disclosure.

FIG. 10 is a diagram for explaining a height of an electrode portion of an electrode unit in a modified example 3 of the present disclosure.

### DETAILED DESCRIPTION

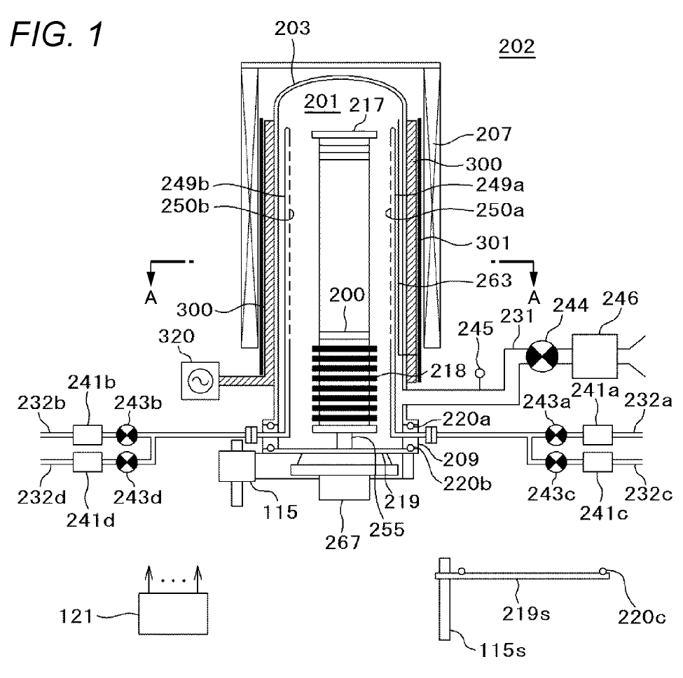

Hereinafter, an embodiment of the present disclosure will be described with reference to FIGS. 1 to 7. Note that the drawings used in the following description are all schematic, and a dimensional relationship between elements, a ratio between elements, and the like illustrated in the drawings do not necessarily coincide with actual ones. Between a plurality of drawings, the dimensional relationships between the elements, the ratios between the elements, and the like do not necessarily coincide with each other. Unless otherwise noted in the specification, each element is not limited to one in number and thus may be two or more in number.

### 1 Configuration of Substrate Processing Apparatus

### Heating Device

As illustrated in FIG. 1, a processing furnace 202 of a vertical substrate processing apparatus includes a heater 207 serving as a heating device. The heating device is also referred to as a heating mechanism or a heating portion. The heater 207 has a cylindrical shape and is supported by a holding plate to be vertically installed. The heater 207 further serves as an activation mechanism that thermally activates (excites) gas. The activation mechanism is also referred to as an exciter.

### Process Chamber

An electrode fixture 301 to be described later is disposed inside the heater 207, and furthermore, an electrode 300 of a plasma generator to be described later is disposed inside the electrode fixture 301. Furthermore, inside the electrode 300, a reaction tube 203 is disposed concentrically with the heater 207. The reaction tube 203 is made of, for example, a heat-resistant material such as quartz (SiO ₂) or silicon carbide (SiC), and is formed in a cylindrical shape with an upper end closed and a lower end opened. A manifold 209 is disposed below the reaction tube 203 concentrically with the reaction tube 203. For example, the manifold 209 is made of metal, such as stainless steel (SUS), and is formed in a cylindrical shape with an upper end and a lower end opened. An upper end portion of the manifold 209 is engaged with a lower end portion of the reaction tube 203 and is configured to support the reaction tube 203. An O-ring 220a serving as a seal member is provided between the manifold 209 and the reaction tube 203. The manifold 209 is supported by a heater base, and thus, the reaction tube 203 is vertically installed. A processing container is mainly configured by the reaction tube 203 and the manifold 209. The processing container is also referred to as a reaction container. A process chamber 201 is formed in a cylindrical hollow portion of the processing container. The process chamber 201 is capable of housing wafers 200 serving as a plurality of substrates. The wafer 200 is processed in the process chamber 201. However, the processing container is not limited to the configuration described above, and in some cases, only the reaction tube 203 is referred to as the processing container.

### Gas Supplier

In the process chamber 201, nozzles 249a and 249b serving, respectively, as first and second suppliers are provided so as to penetrate through the side wall of the manifold 209. The nozzles 249a and 249b are also referred to as first and second nozzles, respectively. The nozzles 249a and 249b are each made of, for example, a heat-resistant material such as quartz or SiC. To the nozzles 249a and 249b, gas supply pipes 232a and 232b are connected, respectively. As described above, in the processing container, the two nozzles 249a and 249b and the two gas supply pipes 232a and 232b are disposed such that a plurality of types of gases can be supplied into the process chamber 201. Note that when only the reaction tube 203 is used as the processing container, the nozzles 249a and 249b may be disposed so as to penetrate a side wall of the reaction tube 203.

The gas supply pipe 232a is provided with a mass flow controller (MFC) 241a serving as a flow rate controller and a valve 243a serving as an on/off valve in the order from the upstream side of a gas flow. The gas supply pipe 232b is provided with a mass flow controller (MFC) 241b serving as a flow rate controller and a valve 243b serving as an on/off valve in the order from the upstream side of a gas flow. The flow rate controller is also referred to as a flow rate control portion. Gas supply pipes 232c and 232d that supply inert gas are connected to the downstream sides of the valves 243a and 243b of the gas supply pipes 232a and 232b, respectively. In gas supply pipes 232c and 232d, MFCs 241c and 241d and valves 243c and 243d are disposed in this order from an upstream side, respectively.

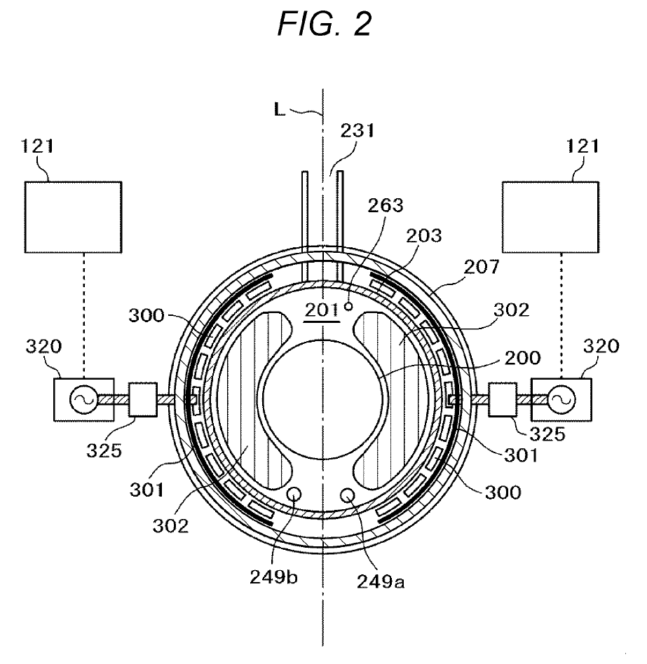

As illustrated in FIGS. 1 and 2, the nozzles 249a and 249b are disposed in an annular space in plan view between an inner wall of the reaction tube 203 and the wafers 200 so as to rise upward in a loading direction of the wafers 200 from a lower portion of the inner wall of the reaction tube 203 to an upper portion thereof along the inner wall. That is, the nozzles 249a and 249b are disposed perpendicularly to surfaces (flat surfaces) of the wafers 200 carried in the process chamber 201 on a lateral side of end portions (that is, peripheral edge portions) of the wafers 200. The nozzle 249a has a side face provided with a gas supply hole 250a for supplying gas. The nozzle 249b has a side face provided with a gas supply hole 250b for supplying gas. The gas supply hole 250a opens so as to face the center of the reaction tube 203, and can supply gas toward the wafers 200. A plurality of the gas supply holes 250a and a plurality of the gas supply holes 250b are formed from a lower portion of the reaction tube 203 to an upper portion thereof.

As described above, in the present embodiment, gas is transferred via the nozzles 249a and 249b disposed in an annular and longitudinally long space in plan view, defined by an inner wall of a side wall of the reaction tube 203 and end portions of the plurality of wafers 200 arranged in the reaction tube 203, that is, in a cylindrical space. Then, gas is ejected into the reaction tube 203 for the first time in the vicinity of the wafers 200 from the gas supply holes 250a and 250b opened in the nozzles 249a and 249b, respectively. A main flow of the gas in the reaction tube 203 is a direction parallel to surfaces of the wafers 200, that is, a horizontal direction. According to such a configuration, gas can be uniformly supplied to each of the wafers 200, and the uniformity of a thickness of a film to be formed on each of the wafers 200 can be improved. The gas that has flowed on the surface of the wafer 200, that is, the remaining gas after the reaction flows towards the direction of an exhaust port, that is, an exhaust pipe 231 to be described later. However, the direction of the flow of the remaining gas is appropriately specified by the position of the exhaust port, and is not limited to the vertical direction.

A source (source gas) is supplied from the gas supply pipe 232a into the process chamber 201 via the MFC 241a, the valve 243a, and the nozzle 249a.

A reactant (reactant gas) is supplied from the gas supply pipe 232b into the process chamber 201 via the MFC 241b, the valve 243b, and the nozzle 249b.

Inert gas is supplied from the gas supply pipes 232c and 232d into the process chamber 201 via the MFCs 241c and 241d, the valves 243c and 243d, and the nozzles 249a and 249b, respectively.

A source supply system serving as a first gas supply system is mainly formed by the gas supply pipe 232a, the MFC 241a, and the valve 243a. A reactant supply system (reactant gas supply system) serving as a second gas supply system is mainly formed by the gas supply pipe 232b, the MFC 241b, and the valve 243b. An inert gas supply system is mainly formed by the gas supply pipes 232c and 232d, the MFCs 241c and 241d, and the valves 243c and 243d. The source supply system, the reactant supply system, and the inert gas supply system are also simply referred to as a gas supply system or a gas supplier.

### Substrate Support

As illustrated in FIG. 1, a boat 217 serving as a substrate support is configured to support a plurality of, for example, 25 to 200 wafers 200 in multiple stages, that is, to arrange the wafers 200 at intervals, while the wafers 200 are aligned in the vertical direction in a horizontal posture and in a state where the centers thereof are aligned with one another. The boat 217 is made of, for example, a heat-resistant material such as quartz or SiC. For example, a heat insulating plate 218 that is made of a heat-resistant material such as quartz or SiC is supported at a lower portion of the boat 217 in multiple stages. With this configuration, heat from the heater 207 is less likely to be transferred to a seal cap 219 side. However, the present embodiment is not limited to such a form. For example, a heat insulating tube configured as a cylindrical member made of a heat-resistant material such as quartz or SiC may be disposed without disposing the heat insulating plate 218 at the lower portion of the boat 217.

### Plasma Generator

Next, a plasma generator will be described with reference to FIGS. 1 to 5.

An electrode 300 for plasma generation is provided outside the reaction tube 203, that is, outside the process chamber 201. By applying power to the electrode 300, it is possible to turn gas into plasma and excite the plasma inside the reaction tube 203, that is, inside the process chamber 201, that is, it is possible to excite the gas into a plasma state. Hereinafter, exciting the gas into a plasma state is simply applied so that the plasma generates capacitively coupled plasma (CCP) in the reaction tube 203, that is, in the process chamber 201.

Specifically, as illustrated in FIG. 2, the electrode 300 and the electrode fixture 301 for fixing the electrode 300 are arranged between the heater 207 and the reaction tube 203. The electrode fixture 301 is arranged inside the heater 207, the electrode 300 is arranged inside the electrode fixture 301, and the reaction tube 203 is arranged inside the electrode 300.

In addition, as illustrated in FIGS. 1 and 2, the electrode 300 and the electrode fixture 301 are provided in an annular space in plan view between the inner wall of the heater 207 and the outer wall of the reaction tube 203 so as to extend in the arrangement direction of the wafers 200 from a lower portion of the outer wall of the reaction tube 203 to an upper portion thereof along the outer wall. The electrode 300 is provided in parallel with the nozzles 249a and 249b. The electrode 300 and the electrode fixture 301 are arranged and disposed concentrically with the reaction tube 203 and the heater 207 and not in contact with the heater 207 in plan view. The electrode fixture 301 is made of an insulating substance (that is, an insulator), and is provided so as to cover at least a part of the electrode 300 and the reaction tube 203. Thus, the electrode fixture 301 can also be referred to as a cover (quartz cover, insulating wall, insulating plate) or a cross-sectional arc cover (cross-sectional arc body, cross-sectional arc wall).

As illustrated in FIG. 2, a plurality of electrodes 300 is provided, and the plurality of electrodes 300 is fixed to and installed on the inner wall of the electrode fixture 301. Here, the electrode fixture 301 and the electrode 300 can also be referred to as an electrode unit. As illustrated in FIG. 2, the electrode unit is preferably disposed at a position avoiding the nozzles 249a and 249b and the exhaust pipe 231. FIG. 2 illustrates an example in which two electrode units are disposed outside the process chamber 201 so as to face each other across the center of the wafer 200 or the reaction tube 203 while avoiding the nozzles 249a and 249b and the exhaust pipe 231. Note that FIG. 2 illustrates an example in which the two electrode units are disposed line-symmetrically, that is, symmetrically with respect to the straight line L in plan view. By arranging the electrode units in this manner, the nozzles 249a and 249b, a temperature sensor 263, and the exhaust pipe 231 can be disposed outside the plasma generation region in the process chamber 201. In addition, plasma damage to these members, wear and damage of these members, and generation of particles from these members can be suppressed.

A high frequency of, for example, 25 MHz or more and 35 MHz or less, more specifically, a frequency of 27.12 MHz is input to the electrode 300 from a high frequency power source 320 via a matcher 325, whereby plasma (active species) 302 is generated in the reaction tube 203. The high frequency power source 320 is also referred to as a radio frequency (RF) power supply. According to the plasma generated as described above, the plasma 302 for substrate processing can be supplied to the surface of the wafer 200 from the periphery of the wafer 200. Power is supplied from the lower side (lower end) of the electrode 300.

Mainly, the electrode 300, that is, a first electrode 300-1 and a second electrode 300-2 constitute the plasma generator that excites (activates) gas into a plasma state. The plasma generator is also referred to as a plasma exciter or a plasma activation mechanism. The electrode fixture 301, the matcher 325, and the high frequency power source 320 may be included in the plasma generator.

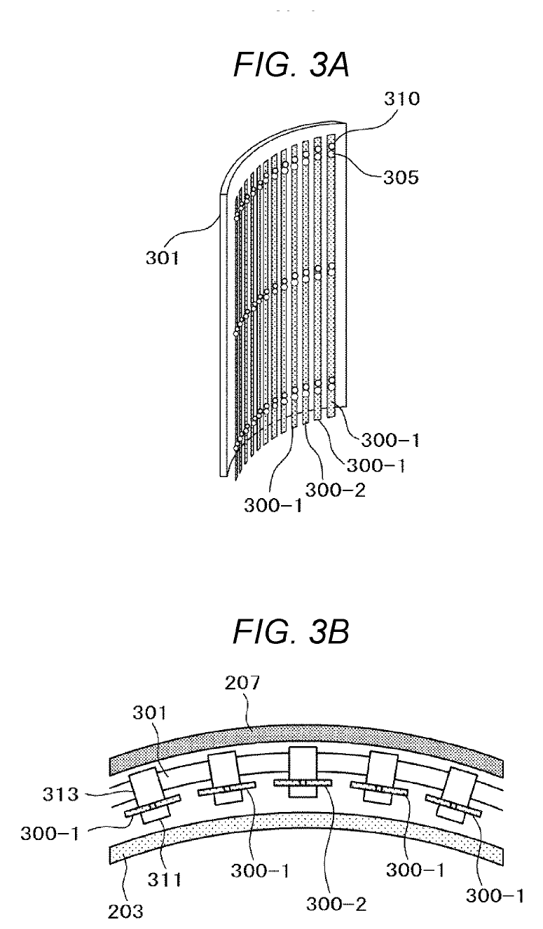

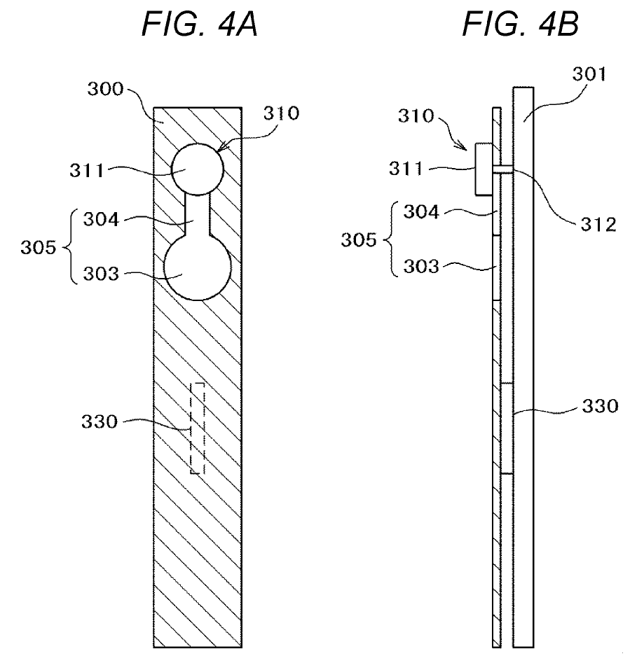

A basic structure of the electrode unit will be described with reference to FIGS. 3A, 3B, 4A, and 4B.

As illustrated in FIGS. 3A and 3B, the electrode 300 includes the first electrode (first electrode) 300-1 and the second electrode (second electrode) 300-2. The first electrode 300-1 is connected to the high frequency power source 320 via the matcher 325, and an arbitrary potential is applied thereto. In other words, high frequency power is applied to the first electrode 300-1. The second electrode 300-2 is grounded and has a reference potential (0 V). In other words, the reference potential is applied to the second electrode 300-2. The first electrode 300-1 is also referred to as a Hot electrode or a HOT electrode, and the second electrode 300-2 is also referred to as a Ground electrode or a GND electrode. Each of the first electrode 300-1 and the second electrode 300-2 is configured as a plate-like member in a front view. At least one first electrode 300-1 is provided, and at least one second electrode 300-2 is provided. FIGS. 3A and 3B illustrate an example in which a plurality of first electrodes 300-1 and a plurality of second electrodes 300-2 are provided, and FIG. 3A illustrates an example in which eight first electrodes 300-1 and four second electrodes 300-2 are provided. By applying high frequency power between the first electrode 300-1 and the second electrode 300-2 from the high frequency power source 320 via the matcher 325, plasma is generated in a region between the first electrode 300-1 and the second electrode 300-2. These regions are also referred to as plasma generation regions. In the present disclosure, the first electrode 300-1 and the second electrode 300-2 are described as the electrode 300 in a case where it is not necessary to particularly distinguish these electrodes.

Note that, as illustrated in FIG. 1, the electrode 300 is disposed in a direction perpendicular to the processing container (vertical direction, direction in which a substrate is stacked). In addition, as illustrated in FIGS. 2 and 3B, the electrodes 300 are arranged in an arc shape in plan view, at equal intervals, that is, so that distances (gaps) between the adjacent electrodes 300 (for example, between the first electrode 300-1 and the second electrode 300-2.) are equal. In addition, the electrodes 300 are arranged in a substantially arc shape in plan view between the reaction tube 203 and the heater 207 along the outer wall of the reaction tube 203, and are arranged to be fixed to an inner wall surface of the electrode fixture 301 formed in an arc shape having a central angle of 30 degrees or more and 240 degrees or less, for example. In addition, as described above, the electrode 300 is provided in parallel with the nozzles 249a and 249b.

The electrode 300 (first electrode 300-1, second electrode 300-2) is made of an oxidation-resistant material such as nickel (Ni). The electrode 300 can be made of a metal material such as SUS, aluminum (Al), or copper (Cu). However, when the electrode is made of an oxidation-resistant material such as Ni, a decrease in electrical conductivity can be suppressed, and accordingly, a decrease in plasma generation efficiency can be suppressed. Furthermore, the electrode 300 can be made of a Ni alloy material to which Al is added. In this case, an aluminum oxide film (AlO film) which is an oxidation film having high heat resistance and corrosion resistance can be formed on the outermost surface of the electrode 300. Since the AlO film formed on the outermost surface of the electrode 300 acts as a protective film (block film, barrier film), it is possible to suppress the progress of degradation inside the electrode 300. As a result, it is possible to further suppress a decrease in plasma generation efficiency due to a decrease in electrical conductivity of the electrode 300. The electrode fixture 301 is made of an insulating substance (insulator), for example, a heat-resistant material such as quartz or SiC. The material of the electrode fixture 301 is preferably similar to the material of the reaction tube 203.

The electrode 300 is preferably configured to have sufficient strength, and to have a thickness of 0.1 mm or more and 1 mm or less and a width of 5 mm or more and 30 mm or less so as not to significantly lower efficiency of wafer heating by a heat source. In addition, it is preferable to have a bending structure as a deformation suppressor for preventing deformation due to heating by the heater 207. In this case, since the electrode 300 is disposed between the reaction tube 203 and the heater 207, the bending angle is appropriately 90° to 175° due to space constraints. A film formed on the electrode surface by thermal oxidation may be peeled off by thermal stress to generate particles, so that it is necessary to pay attention to excessive bending.

As illustrated in FIGS. 4A and 4B, a protrusion (hook) 310 capable of hooking the electrode 300 is provided on an inner wall surface of the electrode fixture 301, and an opening 305 which is a through hole through which the protrusion 310 can be inserted is provided in the electrode 300. The opening 305 includes a circular notch portion 303 through which a protrusion head portion 311 passes and a slide notch portion 304 for sliding a protrusion shaft portion 312. The electrode 300 can be fixed to the electrode fixture 301 by hooking the electrode 300 on the protrusion 310 provided on the inner wall surface of the electrode fixture 301 through the opening 305. Note that FIG. 3A illustrates an example in which two openings 305 are provided for one electrode 300, and two protrusions 310 are hooked and fixed for one electrode 300, that is, an example in which one electrode is fixed at two locations.

The plurality of electrodes 300 provided is fixed to an inner wall surface of the electrode fixture 301 which is a curved electrode fixture, and unitized (hook type electrode unit) so as to be integrated with the electrode fixture 301, and installed on the outer periphery of the reaction tube 203. Quartz is adopted as a material of the electrode fixture 301. In order to keep the distance between the electrode fixture 301 or the reaction tube 203 and the electrode 300 constant, the electrode fixture 301 or the electrode 300 may have an elastic body such as a spacer or a spring, and these may have a structure integrated with the electrode fixture 301 or the electrode 300. In the present embodiment, as illustrated in FIG. 4B, a spacer 330 has a structure integrated with the electrode fixture 301. It is more effective to dispose a plurality of the spacers 330 for one electrode 300 in order to fix the electrode 300 with a distance between the electrode fixture 301 or the reaction tube 203 and the electrode 300 constant. Here, the spacer 330 may be included in the above-described electrode unit.

The electrode fixture 301 is preferably configured to have sufficient strength, and to have a thickness of 1 mm or more and 5 mm or less so as not to significantly lower efficiency of wafer heating by the heater 207. If the thickness of the electrode fixture 301 is less than 1 mm, a predetermined strength against the weight of the electrode fixture 301 itself, a temperature change, and the like cannot be obtained. In addition, if the thickness is larger than 5 mm, thermal energy radiated from the heater 207 is absorbed, so that the heat treatment of the wafer 200 cannot be appropriately performed.

Here, a pressure in the furnace during substrate processing is preferably controlled in a range of 10 Pa or more and 300 Pa or less. This is because when the pressure in the furnace is lower than 10 Pa, a mean free path of gas molecules is longer than Debye length of plasma, plasma directly hitting a furnace wall is significant, and therefore it is difficult to suppress generation of particles. In addition, in a case where the pressure in the furnace is higher than 300 Pa, since the plasma generation efficiency is saturated, the plasma generation amount does not change even if the reactant gas is supplied, and the reactant gas is wastefully consumed. In addition, since the mean free path of the gas molecules is shortened, the transport efficiency of the plasma active species to the wafer is deteriorated.

In order to obtain high substrate processing capability at a substrate temperature of 500°C or less, it is desirable that the occupancy of the electrode fixture 301 is set to a substantially arc shape having a central angle of 30° or more and 240° or less. In addition, in order to avoid generation of particles, it is desirable to dispose the exhaust pipe 231, which is an exhaust port, the nozzles 249a and 249b, and the like, to be avoided. That is, the electrode fixture 301 is disposed on the outer periphery of the reaction tube 203 other than the position where the nozzles 249a and 249b serving as the gas suppliers and the exhaust pipe 231 serving as the gas exhauster provided in the reaction tube 203 are installed. In the present embodiment, two electrode fixtures 301 having a central angle of 110° are installed symmetrically.

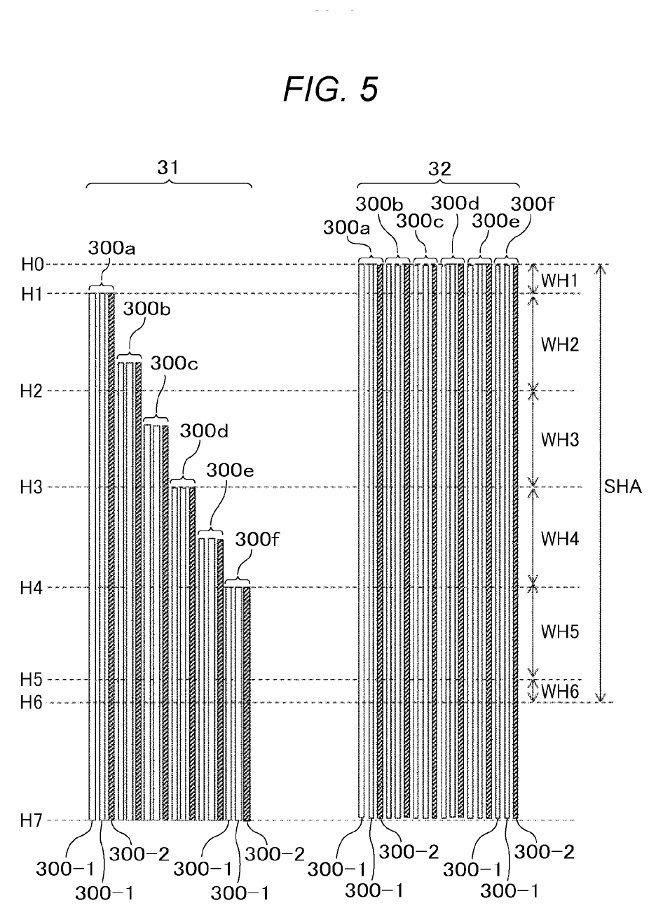

Specific examples of the electrodes used in the two electrode units illustrated in FIG. 2 will be described with reference to FIG. 5.

In each of first and second electrode units (first unit and second unit) 31 and 32, six sets of electrode portions each including two first electrodes (first electrodes) 300-1 and one second electrode (second electrode) 300-2 are arranged. The six sets of first to sixth electrode portions (first to sixth electrode portions) 300a to 300f are arranged in this order from the left side of FIG. 5. The electrode portions 300a to 300f of the electrode unit 31 are also referred to as a first electrode group, and the electrode portions 300a to 300f of the electrode unit 32 are also referred to as a second electrode group. The first electrodes 300-1 are arranged in succession. Then, the first electrode 300-1, the first electrode 300-1, and the second electrode 300-2 are arranged in this order. The number of the first electrodes 300-1 is not limited to two, and may be two or more. In this case, one second electrode 300-2 is provided for the plurality of first electrodes 300-1. The number of the second electrodes 300-2 is not limited to one, and is different from the number of the first electrodes 300-1.

In the electrode unit 31, the positions (heights) of the upper end portions of the first electrodes 300-1 and the second electrode 300-2 of each of the electrode portions 300a to 300f are the same, and the electrodes extend from a position (H7) below the lower end of a substrate holding region SHA to a part of the substrate holding region SHA. In other words, the lengths of the first electrodes 300-1 and the second electrode 300-2 of each of the electrode portions 300a to 300f are the same. The heights of the electrode portions 300a to 300f decrease in this order. Note that, the first electrode and the second electrode may have substantially the same length.

Here, the substrate holding region SHA means a region where the wafers 200 are held in the boat 217. In addition, the wafer 200 means at least one of a product wafer, a dummy wafer, and a fill dummy wafer. The substrate holding region SHA is divided into six regions WH1 to WH6 in the height direction, and the positions (heights) of the boundaries are set to H1, H2, H3, H4, and H5 in order from the top. For example, regions WH2 to WH5 have substantially the same width, the region WH1 is narrower than the region WH2, and the region WH6 is narrower than the region WH1. The dummy wafer is placed in the upper portion or the entire region of the region WH1 and the lower portion or the entire region of the region WH6, and the substrate processing region is narrower than the substrate holding region SHA. The position (height) of the upper end of the substrate holding region SHA is set to H0, and the position (height) of the lower end is set to H6.

The heights of the upper ends of the first electrodes 300-1 and the second electrode 300-2 of a first electrode portion 300a of the electrode unit 31 are the height of H1, and are lower than H0 which is the height of the distal ends of the first electrodes 300-1 and the second electrode 300-2 of the electrode unit 32. The heights of the upper ends of the first electrodes 300-1 and the second electrode 300-2 of a second electrode portion 300b of the electrode unit 31 are lower than the height of H1 and higher than the height of H2. The heights of the upper ends of the first electrodes 300-1 and the second electrode 300-2 of a third electrode portion 300c of the electrode unit 31 are lower than the height of H2 and higher than the height of H3.

In other words, the lengths of the first electrodes 300-1 and the second electrode 300-2 of the first electrode portion 300a are longer than the lengths of the first electrodes 300-1 and the second electrode 300-2 of the second electrode portion 300b. The lengths of the first electrodes 300-1 and the second electrode 300-2 of the second electrode portion 300b are shorter than the lengths of the first electrodes 300-1 and the second electrode 300-2 of the first electrode portion 300a. In addition, the lengths of the first electrodes 300-1 and the second electrode 300-2 of the second electrode portion 300b are longer than the lengths of the first electrodes 300-1 and the second electrode 300-2 of the third electrode portion 300c. The lengths of the first electrodes 300-1 and the second electrode 300-2 of the third electrode portion 300c are shorter than the lengths of the first electrodes 300-1 and the second electrode 300-2 of the first electrode portion 300a. In addition, the lengths of the first electrodes 300-1 and the second electrode 300-2 of the third electrode portion 300c are shorter than the lengths of the first electrodes 300-1 and the second electrode 300-2 of the second electrode portion 300b. The lengths of the first electrodes 300-1 and the second electrode 300-2 of the first electrode portion 300a of the electrode unit 31 is shorter than the lengths of the first electrodes 300-1 and the second electrode 300-2 of the electrode unit 32.

The heights of the upper ends of the first electrodes 300-1 and the second electrode 300-2 of a fourth electrode portion 300d of the electrode unit 31 are the height of H3. The heights of the upper ends of the first electrodes 300-1 and the second electrode 300-2 of a fifth electrode portion 300e of the electrode unit 31 are lower than the height of H3 and higher than the height of H4. The heights of the upper ends of the first electrodes 300-1 and the second electrode 300-2 of a sixth electrode portion 300f of the electrode unit 31 are the height of H4.

In the electrode unit 32, the positions (heights) of the upper ends of the first electrodes 300-1 and the second electrode 300-2 of each of the electrode portions 300a to 300f are the same. In addition, the first electrodes 300-1 and the second electrode 300-2 of each of the electrode portions 300a to 300f extend from the position (H7) below the lower end of the substrate holding region SHA to the upper end (H0) of the substrate holding region SHA. In other words, the lengths of the first electrodes 300-1 and the second electrode 300-2 of each of the electrode portions 300a to 300f are the same.

For example, the width of each of the first electrode 300-1 and the second electrode 300-2 is 12.5 mm. The gap between the first electrode 300-1 and the first electrode 300-1 and the gap between the first electrode 300-1 and the second electrode 300-2 are all 7.5 mm.

### EXHAUSTER

In the reaction tube 203, the exhaust pipe 231 that exhausts an atmosphere in the process chamber 201 is disposed as illustrated in FIG. 1. A vacuum pump 246 serving as a vacuum exhaust device is connected to the exhaust pipe 231 via a pressure sensor 245 serving as a pressure detector that detects the pressure in the process chamber 201 and an auto pressure controller (APC) valve 244 serving as an exhaust valve. The pressure detector is also referred to as a pressure detection portion, and the exhaust valve is also referred to as a pressure regulator. The APC valve 244 is a valve that can perform vacuum exhaust and stop vacuum exhaust in the process chamber 201 by opening and closing the valve in a state where the vacuum pump 246 is operated. The APC valve 244 is a valve configured to be able to regulate the pressure in the process chamber 201 by regulating the degree of valve opening on the basis of the pressure information detected by the pressure sensor 245 in a state where the vacuum pump 246 is operated. An exhaust system is configured mainly by the exhaust pipe 231, the APC valve 244, and the pressure sensor 245. The vacuum pump 246 may be included in the exhaust system. The exhaust pipe 231 does not have to be disposed in the reaction tube 203, and may be disposed in the manifold 209 similarly to the nozzles 249a and 249b.

### Peripheral Device

Below the manifold 209, the seal cap 219 serving as a furnace opening lid capable of airtightly closing a lower end opening of the manifold 209 is provided. The seal cap 219 is configured to abut against the lower end of the manifold 209 from a lower side in the vertical direction. The seal cap 219 is made of, for example, a metal such as SUS, and is formed in a disk shape. An O-ring 220b serving as a seal member that abuts the lower end of the manifold 209 is provided on an upper surface of the seal cap 219.

On a side of the seal cap 219 opposite to the process chamber 201, a rotation mechanism 267 that rotates the boat 217 is installed. A rotation shaft 255 of the rotation mechanism 267 penetrates the seal cap 219 and is connected to the boat 217. The rotation mechanism 267 is configured to rotate the wafers 200 by rotating the boat 217. The seal cap 219 is configured to be raised and lowered in the vertical direction by a boat elevator 115 serving as a raising/lowering mechanism vertically installed outside the reaction tube 203. The boat elevator 115 is configured to be capable of carrying in the boat 217 in the process chamber 201 and carrying out the boat 217 from the process chamber 201 by raising and lowering the seal cap 219.

The boat elevator 115 is configured as a transfer device that transfers the boat 217, that is, the wafers 200 to the inside and the outside of the process chamber 201. The transfer device is also referred to as a transfer mechanism. In addition, a shutter 219s serving as a furnace opening lid that is capable of airtightly closing a lower end opening of the manifold 209 while the seal cap 219 is lowered by the boat elevator 115 is provided below the manifold 209. The shutter 219s is made of, for example, a metal such as SUS, and is formed in a disk shape. An O-ring 220c serving as a seal member that abuts the lower end of the manifold 209 is provided on an upper surface of the shutter 219s. The opening/closing operation (for example, a raising/lowering operation, a turning operation, or the like) of the shutter 219s is controlled by a shutter opening/closing mechanism 115s.

In the reaction tube 203, the temperature sensor 263 serving as a temperature detector is installed. By regulating a degree of energization to the heater 207 on the basis of temperature information detected by the temperature sensor 263, the temperature in the process chamber 201 has desired temperature distribution. The temperature sensor 263 is provided along an inner wall of the reaction tube 203 similarly to the nozzles 249a and 249b.

### Control Device

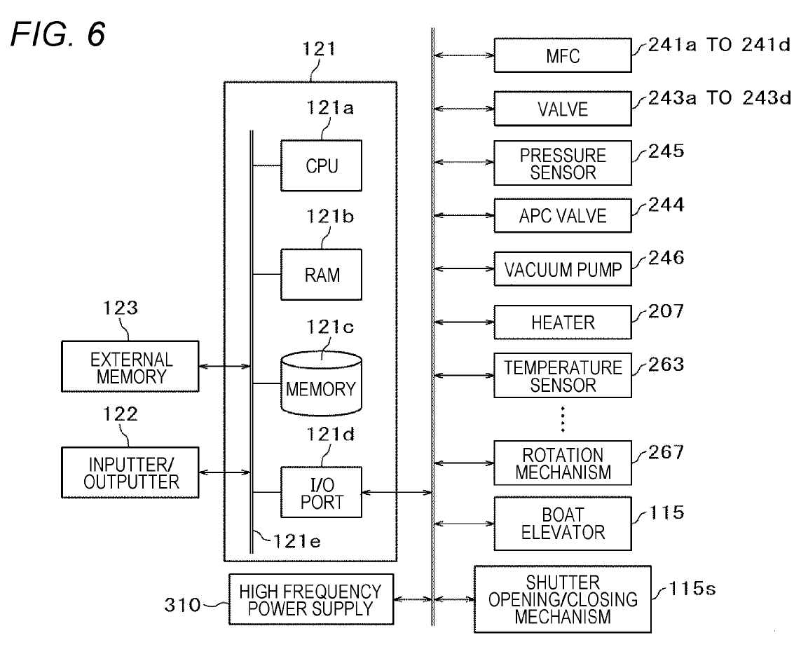

Next, a control device will be described with reference to FIG. 6. As illustrated in FIG. 6, a controller 121 that is a controller (control device) is configured as a computer including a central processing unit (CPU) 121a, a random access memory (RAM) 121b, a memory 121c, and an I/O port 121d. The RAM 121b, the memory 121c, and the I/O port 121d are configured to be able to exchange data with the CPU 121a via an internal bus 121e. An inputter/outputter 122 configured as, for example, a touch panel and the like is connected to the controller 121.

The memory 121c includes, for example, a flash memory, a hard disk drive (HDD), a solid state drive (SSD) and the like. In the memory 121c, a control program that controls an operation of the substrate processing apparatus, a process recipe in which a procedure, a condition, or the like for film-forming processing, to be described later, is described, and the like are stored to be readable. The process recipe is a combination of procedures in various processing (for example, film-forming processing) to be described later so that the controller 121 causes the substrate processing apparatus to execute the procedures to obtain a predetermined result, and functions as a program. Hereinafter, the process recipe, the control program and the like are collectively and simply referred to as a program. In addition, the process recipe is simply referred to as a recipe. In a case where the term “program” is used in the present specification, this might include the recipe alone, the control program alone, or both of them. The RAM 121b is configured as a memory region (work area) in which programs, data and the like read by the CPU 121a are temporarily stored.

The I/O port 121d is connected to the MFCs 241a to 241d, the valves 243a to 243d, the pressure sensor 245, the APC valve 244, the vacuum pump 246, the heater 207, the temperature sensor 263, the rotation mechanism 267, the boat elevator 115, the shutter opening/closing mechanism 115s, the high frequency power source 320, and the like described above.

The CPU 121a reads the control program from the memory 121c and executes the control program, and additionally reads the recipe from the memory 121c in response to an operation command input from the inputter/outputter 122. According to the content of the read recipe, the CPU 121a is configured to be able to control the rotation mechanism 267, the flow rate regulation operation of various gas by the MFCs 241a to 241d, the opening/closing operation of the valves 243a to 243d, the opening/closing operation of the APC valve 244, the pressure regulation operation by the APC valve 244 based on the pressure sensor 245, and the start and stop of the vacuum pump 246. According to the contents of the read recipe, the CPU 121a is further configured to be able to control temperature regulation operation of the heater 207 based on the temperature sensor 263, forward and reverse rotation of the boat 217 by the rotation mechanism 267, a rotation angle and rotation speed regulation operation, a raising/lowering operation of the boat 217 by the boat elevator 115, an opening/closing operation of the shutter 219s by the shutter opening/closing mechanism 115s, power supply of the high frequency power source 320, and the like.

The controller 121 can be composed by installation of the above-described program stored in an external memory 123 into the computer. The external memory includes, for example, a magnetic disk such as a hard disk, an optical disk such as a CD, a magneto-optical disk such as an MO, or a semiconductor memory such as a USB memory. The memory 121c and the external memory 123 are configured as computer-readable recording media. Hereinafter, they are collectively and simply referred to as recording media. In a case where the term “recording medium” is used in the present specification, this might include the memory 121c alone, the external memory 123 alone, or both of them. However, the program may be provided to the computer by using a communicator such as the Internet or a dedicated line without using the external memory 123.

2 Substrate Processing Step

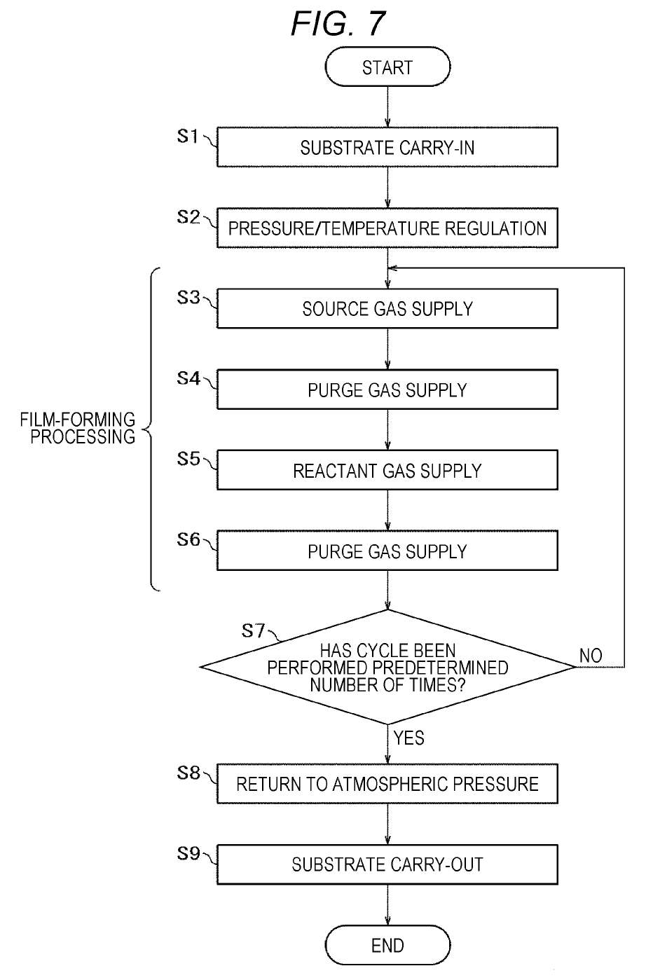

A process example of forming a film on a substrate will be described with reference to FIG. 7 as one of semiconductor device (device) manufacturing steps using the substrate processing apparatus described above. In the following description, an operation of each unit included in the substrate processing apparatus is controlled by the controller 121.

In the present specification, in some cases, the sequence of the film-forming processing illustrated in FIG. 7 is illustrated as follows for convenience. Similar notation will be also used in description of the following modified examples and other embodiments.

Source Gas → Reactant Gas × n

In a case where the term “wafer” is used in the present specification, this might mean a wafer itself, or mean a laminate of the wafer and a predetermined layer, a film or the like formed on a surface thereof. In a case where the term “surface of the wafer” is used in the present specification, this might mean the surface of the wafer itself or mean the surface of a predetermined layer, a film or the like formed on the wafer. In a case where the term “substrate” is used in the present specification, this is a synonym of the term “wafer”.

Carrying-in Step: S1

In a case where the plurality of wafers 200 is charged in the boat 217 (wafer charging), the shutter 219s is moved by the shutter opening/closing mechanism 115s, and the lower end opening of the manifold 209 is opened (shutter opening). Thereafter, as illustrated in FIG. 1, the boat 217 supporting the plurality of wafers 200 is raised by the boat elevator 115 and is carried in the process chamber 201 (boat load). In this state, the lower end of the manifold 209 is sealed with the seal cap 219 via the O-ring 220b.

Pressure and Temperature Regulation Step: S2

The inside of the process chamber 201 is subjected to vacuum exhaust (decompression exhaust) by the vacuum pump 246 so as to have a desired pressure (degree of vacuum). At this time, the pressure in the process chamber 201 is measured by the pressure sensor 245, and the APC valve 244 is feedback-controlled based on the measured pressure information (pressure regulation). The vacuum pump 246 maintains a state of being constantly operated at least until a film-forming step to be described later is ended.

In addition, the inside of the process chamber 201 is heated by the heater 207 so as to have a desired temperature. At this time, a degree of energization to the heater 207 is feedback-controlled and the temperature is regulated on the basis of the temperature information detected by the temperature sensor 263 so that the inside of the process chamber 201 has a desired temperature distribution. The heating of the inside of the process chamber 201 by the heater 207 is continuously performed at least until the film-forming step to be described later is ended. Note that when the film-forming step is performed under a temperature condition of room temperature or lower, the inside of the process chamber 201 does not have to be heated by the heater 207. However, when only processing under such a temperature is performed, the heater 207 is unnecessary, and the heater 207 does not have to be provided in the substrate processing apparatus. In this case, it is possible to simplify the configuration of the substrate processing apparatus.

Subsequently, the rotation of the boat 217 and the wafer 200 by the rotation mechanism 267 is started. The rotation of the boat 217 and the wafers 200 by the rotation mechanism 267 is continuously performed at least until the film-forming step to be described later is ended.

Film-forming Step: S3, S4, S5, and S6

Thereafter, steps S3, S4, S5, and S6 are sequentially executed to perform the film-forming step.

Source Gas Supplying Step: S3 and S4

In step S3, source gas is supplied to the wafers 200 in the process chamber 201.

The valve 243a is opened to flow the source gas into the gas supply pipe 232a. A flow rate of the source gas is regulated by the MFC 241a, and the source gas is supplied into the process chamber 201 from the gas supply hole 250a through the nozzle 249a, and is exhausted from the exhaust pipe 231. In this case, the source gas is supplied to the wafers 200. At the same time, the valve 243c may be opened to allow the inert gas to flow into the gas supply pipe 232c. A flow rate of the inert gas is regulated by the MFC 241c, and the inert gas is supplied into the process chamber 201 together with the source gas, and then is exhausted through the exhaust pipe 231.

In addition, in order to prevent the source gas from entering the nozzle 249b, the valve 243d may be opened to allow the inert gas to flow into the gas supply pipe 232d. The inert gas is supplied into the process chamber 201 through the gas supply pipe 232d and the nozzle 249b and then is exhausted through the exhaust pipe 231.

As processing conditions in this step, the following is exemplified:

processing temperature: room temperature (25°C) to 550°C, preferably 400 to 500°C

processing pressure: 1 to 4000 Pa, preferably 100 to 1000 Pa

source gas supply flow rate: 0.1 to 3 slm

source gas supply time: 1 to 100 seconds, preferably 1 to 50 seconds

inert gas supply flow rate (per gas supply pipe): 0 to 10 slm.

Note that, in the present specification, the expression of a numerical range such as “25 to 550°C” means that a lower limit value and an upper limit value are included in the range. Therefore, for example, “25 to 550°C” means “25°C or more and 550°C or less”. The same applies to other numerical ranges. In addition, in the present specification, the processing temperature means the temperature of the wafer 200 or the temperature in the process chamber 201, and the processing pressure means the pressure in the process chamber 201. In addition, the gas supply flow rate: 0 slm means a case where the gas is not supplied. The same applies to the following description. In a case where 0 slm is included in the supply flow rate, 0 slm means a case where the substance (gas) is not supplied. The same applies to the following description.

By supplying the source gas to the wafer 200 under the condition described above, a first layer is formed on the wafer 200 (a base film of the surface). For example, in a case where a silicon (Si)-containing gas to be described later is used as the source gas, the Si-containing layer is formed as the first layer.

After the first layer is formed, the valve 243a is closed, and the supply of the source gas into the process chamber 201 is stopped. At this time, the APC valve 244 is set in an open state, the inside of the process chamber 201 is subjected to vacuum exhaust by the vacuum pump 246, and the unreacted source gas that remains inside the process chamber 201 or the source gas after contributing to the formation of the first layer, a reaction byproduct, or the like is removed from the inside of the process chamber 201 (S4). In addition, the valves 243c and 243d are opened to supply inert gas into the process chamber 201. The inert gas acts as purge gas.

In addition, as the source, for example, a chlorosilane-based gas such as a monochlorosilane (SiH₃Cl) gas, a dichlorosilane (SiH₂Cl₂) gas, a trichlorosilane (SiHCl₃) gas, a tetrachlorosilane (SiCl₄) gas, a hexachlorodisilane (Si_{2C}l₆) gas, or an octachlorotrisilane (Si₃Cl₈) gas, a fluorosilane-based gas such as a tetrafluorosilane (SiF₄) gas or a difluorosilane (SiH_{2F2}) gas, a bromosilane-based gas such as a tetrabromosilane (SiBr₄) gas or a dibromosilane (SiH₂Br₂) gas, or an iodosilane-based gas such as a tetraiodosilane (SiI₄) gas or a diiodosilane (SiH₂I₂) gas can also be used. That is, as the source gas, a halosilane-based gas can be used. One or more of these can be used as the source gas.

As the inert gas, for example, rare gas such as nitrogen (N₂) gas, argon (Ar) gas, helium (He) gas, neon (Ne) gas, or xenon (Xe) gas can be used. The same applies to each step to be described later.

Reactant Gas Supplying Step: S5 and S6

After the film-forming processing is ended, plasma-excited reactant gas is supplied to the wafers 200 in the process chamber 201 (S5).

In this step, opening/closing control of the valves 243b to 243d is performed in the procedure similar to that of the opening/closing control of the valves 243a, 243c, and 243d in step S3. The flow rate of the reactant gas is regulated by the MFC 241b, and the reactant gas is supplied from a gas supply hole 250b into the process chamber 201 through the nozzle 249b. At this time, high frequency power (RF power, frequency of 27.12 MHz in the present embodiment) is supplied (applied) from the high frequency power source 320 to the electrode 300. The reactant gas supplied into the process chamber 201 is excited into a plasma state inside the process chamber 201, is supplied to the wafer 200 as the active species, and is exhausted from the exhaust pipe 231.

As processing conditions in this step, the following is exemplified:

processing temperature: room temperature (25°C) to 550°C, preferably 400 to 500°C processing pressure: 1 to 300 Pa, preferably 10 to 100 Pa

reactant gas supply flow rate: 0.1 to 10 slm

reactant gas supply time: 1 to 100 seconds, preferably 1 to 50 seconds

inert gas supply flow rate (per gas supply pipe): 0 to 10 slm

RF power: 50 to 1000 W

RF frequency: 27.12 MHz.

When the reactant gas is excited into a plasma state and supplied to the wafers 200 under the above-described conditions, ions generated in the plasma and electrically neutral active species are generated. By the action of this active species, the modification processing is performed on the first layer formed on the surface of the wafer 200, and the first layer is modified to the second layer.

When oxidizing gas (oxidizing agent) such as oxygen (O)-containing gas is used as the reactant gas, for example, O-containing active species are generated by exciting the O-containing gas into a plasma state, and the O-containing active species are supplied to the wafer 200. In this case, the oxidizing is performed as the modification processing on the first layer formed on the surface of the wafer 200 by the action of the O-containing active species. In this case, in a case where the first layer is, for example, a Si-containing layer, the Si-containing layer serving as the first layer is modified to a silicon oxide layer (SiO layer) serving as the second layer.

In addition, for example, when nitriding gas (nitriding agent) such as nitrogen (N)-containing and hydrogen (H)-containing gas is used as the reactant gas, N-containing and H-containing active species are generated by exciting the N-containing and H-containing gas into a plasma state. The N-containing and H-containing active species are supplied to the wafer 200. In this case, the nitriding is performed as the modification processing on the first layer formed on the surface of the wafer 200 by the action of the N-containing and H-containing active species. In this case, in a case where the first layer is, for example, a Si-containing layer, the Si-containing layer serving as the first layer is modified to a silicon nitridation layer (SiN layer) serving as the second layer.

After the first layer is modified to the second layer, the valve 243b is closed to stop the supply of the reactant gas. In addition, the supply of the high frequency power to the electrode 300 is stopped. Then, according to the similar processing procedure and the similar processing condition to those of step S4, the reactant gas remaining inside the process chamber 201, or the reaction byproduct is removed from the inside of the process chamber 201 (S6).

As described above, for example, the O-containing gas or the N-containing and H-containing gas can be used as the reactant gas. As the O-containing gas, for example, oxygen (O₂) gas, nitrous oxide (N₂O) gas, nitric oxide (NO) gas, nitrogen dioxide (NO₂) gas, ozone (O₃) gas, hydrogen peroxide (H_{2O2}) gas, water vapor (H₂O), ammonium hydroxide (NH₄ (OH)) gas, carbon monoxide (CO) gas, carbon dioxide (CO₂) gas, or the like can be used. As the N-containing and H-containing gas, hydrogen nitridation-based gas such as ammonia (NH₃) gas, diazene (N_{2H2}) gas, hydrazine (N_{2H4}) gas, and N3H8 gas can be used. As the reactant gas, one or more of these can be used.

As the inert gas, for example, various types of gas exemplified in step S4 can be used.

(Predetermined Number of Times of Execution: S7)

Steps S3, S4, S5, and S6 described above are performed in this order non-simultaneously, that is, without synchronization, as one cycle. Then, by performing this cycle a predetermined number of times (n times, n is an integer of 1 or more), that is, once or more, a film having a predetermined composition and a predetermined thickness of film can be formed on the wafer 200. The cycle described above is preferably repeated a plurality of times. That is, it is preferable to repeat the above-described cycle a plurality of times until the thickness of film formed by making the thickness of the first layer formed per cycle smaller than the desired thickness of film and laminating the second layer becomes the desired thickness of film. Note that, in a case where, for example, a Si-containing layer is formed as the first layer and, for example, a SiO layer is formed as the second layer, a silicon oxide film (SiO film) is formed as a film. In addition, in a case where, for example, a Si-containing layer is formed as the first layer and, for example, a SiN layer is formed as the second layer, a silicon nitride film (SiN film) is formed as a film.

(Step of Returning to Atmospheric Pressure: S8)

When the film forming processing described above is completed, inert gas is supplied into the process chamber 201 from each of the gas supply pipes 232c and 232d, and is exhausted from the exhaust pipe 231. As a result, the inside of the process chamber 201 is purged with the inert gas, and the reactant gas remaining inside the process chamber 201, or the like is removed from the inside of the process chamber 201 (inert gas purge). Thereafter, the atmosphere in the process chamber 201 is replaced with the inert gas (inert gas replacement), and the pressure in the process chamber 201 is returned to normal pressure (return to atmospheric pressure: S8).

Carrying-out Step: S9

Thereafter, the boat elevator 115 lowers the seal cap 219 to open the lower end of the manifold 209. Then, the processed wafer 200 is carried out (boat unload) from the lower end of the manifold 209 to the outside of the reaction tube 203 in a state of being supported by the boat 217. After the boat unload, the shutter 219s is moved to seal the lower end opening of the manifold 209 with the shutter 219s via the O-ring 220c (shutter close). The processed wafer 200 is carried out to the outside of the reaction tube 203, and then, is taken out from the boat 217 (wafer discharge). Additionally, after the wafer discharge, the empty boat 217 may be carried in the process chamber 201.

(3) Effects of the Present Embodiment

In the vicinity of an upper end of the electrode 300, the electric field is stronger than that in other positions of the electrode 300, and the electric field distribution is biased in the longitudinal direction of the electrode 300, and the biased electric field distribution affects the density distribution of the plasma 302 to be biased. Therefore, nonuniformity may appear between the wafers 200 in the thickness of film and film quality having correlation with the density distribution of the plasma 302. This problem can be solved by making the length of the electrode sufficiently longer than the upper end of the substrate holding region SHA. However, by making the length of the electrode longer, the loss of the electrode increases, or the longitudinal direction of the processing furnace 202 increases.

In the present embodiment, the first electrodes 300-1 and the second electrode 300-2 of each of the plurality of electrode portions are configured to have equal lengths. The electrode unit 31 includes a plurality of electrode portions having different lengths, and the heights (that is, the lengths) of the upper end portions of the first electrodes 300-1 and the second electrode 300-2 are adjusted to dispersedly arrange the electrode end portions, which are portions where the electric field is strong, in the substrate holding processing region. With this configuration, the bias of the electric field distribution is improved, and the electric field generated between the inner wall of the reaction tube 203 near the electrode 300 and the wafers 200 is uniformly and strongly distributed in the longitudinal direction (that is, the direction in which the substrates are stacked). As a result, the density of the plasma 302 is high and uniformly distributed in the longitudinal direction, and thus the uniformity of the thickness of film and the film quality between the wafers 200 can be improved.

Modified Example 1

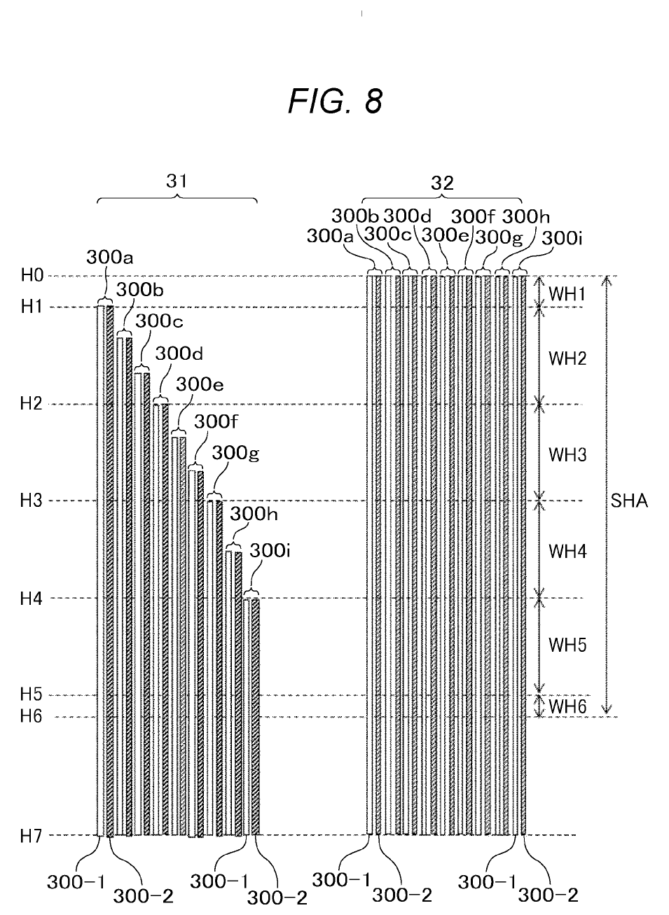

Electrodes used for the electrode units 31 and 32 in a modified example 1 of the embodiment will be described with reference to FIG. 8. In the modified example 1, the electrode arrangement and the electrode length of the electrode portion are different from those in the embodiment. Other configurations of the modified example 1 are similar to those of the embodiment. Also in the modified example 1, effects can be obtained similar to those in the above-described embodiment.

In each of the electrode units 31 and 32, nine sets of electrode portions each including one first electrode 300-1 and one second electrode 300-2 are arranged. The nine sets of first to ninth electrode portions 300a to 300i are arranged in this order from the left side of FIG. 8. Then, the first electrode 300-1 and the second electrode 300-2 are alternately arranged. Each of the number of the first electrodes 300-1 and the number of the second electrodes 300-2 is not limited to one. The first electrode 300-1 and the second electrode 300-2 must be equal in number.

In the electrode unit 31, the positions (heights) of the upper ends of the first electrode 300-1 and the second electrode 300-2 of each of the electrode portions 300a to 300i are the same. The first electrode 300-1 and the second electrode 300-2 of each of the electrode portions 300a to 300i extend from the position (H7) below the lower end of the substrate holding region SHA to a part of the substrate holding region SHA. In other words, the lengths of the first electrode 300-1 and the second electrode 300-2 of each of the electrode portions 300a to 300i are the same. The heights of the electrode portions 300a to 300i decrease in this order.

The heights of the upper ends of the first electrodes 300-1 and the second electrode 300-2 of a first electrode portion 300a of the electrode unit 31 are the height of H1, and are lower than H0 which is the height of the distal ends of the first electrodes 300-1 and the second electrode 300-2 of the electrode unit 32. The heights of the upper ends of the first electrodes 300-1 and the second electrode 300-2 of a second electrode portion 300b of the electrode unit 31 are lower than the height of H1 and higher than the height of H2. The heights of the upper ends of the first electrode 300-1 and the second electrode 300-2 of a third electrode portion 300c of the electrode unit 31 are lower than the height of the second electrode portion 300b and higher than the height of H2.

The heights of the upper ends of the first electrode 300-1 and the second electrode 300-2 of a fourth electrode portion 300d of the electrode unit 31 are the height of H2. The heights of the upper ends of the first electrode 300-1 and the second electrode 300-2 of a fifth electrode portion 300e of the electrode unit 31 are lower than the height of H2 and higher than the height of H3. The heights of the upper ends of the first electrode 300-1 and the second electrode 300-2 of a sixth electrode portion 300f of the electrode unit 31 are lower than the height of the fifth electrode portion 300e and higher than the height of H3.

The heights of the upper ends of the first electrode 300-1 and the second electrode 300-2 of a seventh electrode portion 300g of the electrode unit 31 are the height of H3. The heights of the upper ends of the first electrode 300-1 and the second electrode 300-2 of an eighth electrode portion 300h of the electrode unit 31 are lower than the height of H3 and higher than the height of H4. The heights of the upper ends of the first electrode 300-1 and the second electrode 300-2 of a ninth electrode portion 300i of the electrode unit 31 are the height of H4.

In the electrode unit 32, the positions (heights) of the upper ends of the first electrode 300-1 and the second electrode 300-2 of each of the electrode portions 300a to 300i are the same. The first electrode 300-1 and the second electrode 300-2 of each of the electrode portions 300a to 300i extend from the position (H7) below the lower end of the substrate holding region SHA to the upper end (H0) of the substrate holding region SHA. In other words, the lengths of the first electrode 300-1 and the second electrode 300-2 of each of the electrode portions 300a to 300i are the same.

### Modified Example 2

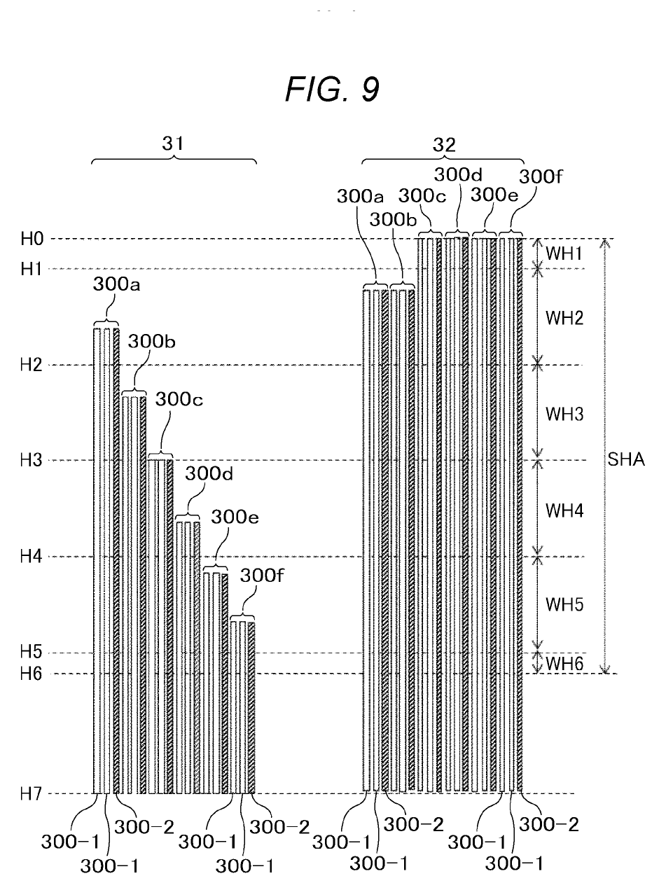

Electrodes used for the electrode units 31 and 32 in a modified example 2 of the embodiment will be described with reference to FIG. 9. In the modified example 2, the electrode length of the electrode portion is different from that of the embodiment. Other configurations of the modified example 2 are similar to those of the embodiment. Also in the modified example 2, effects can be obtained similar to those in the above-described embodiment.

The heights of the upper ends of the first electrodes 300-1 and the second electrode 300-2 of a first electrode portion 300a of the electrode unit 31 are lower than the heights of the distal ends of the first electrodes 300-1 and the second electrode 300-2 of a first electrode portion 300a of the electrode unit 32 and higher than the height of H2. The heights of the upper ends of the first electrodes 300-1 and the second electrode 300-2 of a second electrode portion 300b of the electrode unit 31 are lower than the height of H2 and higher than the height of H3. The heights of the upper ends of the first electrodes 300-1 and the second electrode 300-2 of a third electrode portion 300c of the electrode unit 31 are the height of H3.

The heights of the upper ends of the first electrodes 300-1 and the second electrode 300-2 of a fourth electrode portion 300d of the electrode unit 31 are lower than the height of H3 and higher than the height of H4. The heights of the upper ends of the first electrodes 300-1 and the second electrode 300-2 of a fifth electrode portion 300e of the electrode unit 31 are lower than the height of H4 and higher than the height of H5. The heights of the upper ends of the first electrodes 300-1 and the second electrode 300-2 of a sixth electrode portion 300f of the electrode unit 31 are lower than the height of the fifth electrode portion 300e and higher than the height of H5.

In the electrode unit 32, the positions (heights) of the upper ends of the first electrodes 300-1 and the second electrode 300-2 of each of the electrode portions 300a to 300f are the same. The electrode portions 300a and 300b extend from the position (H7) below the lower end of the substrate holding region SHA to the middle of the region WH2 (between H1 and H2). The electrode portions 300c to 300f extend from the position (H7) below the lower end of the substrate holding region SHA to the upper end (H0) of the substrate holding region SHA. In other words, the lengths of the first electrodes 300-1 and the second electrode 300-2 of each of the electrode portions 300a and 300b are different from the lengths of the first electrodes 300-1 and the second electrode 300-2 of each of the electrode portions 300c to 300f. The lengths of the first electrodes 300-1 and the second electrode 300-2 of the first electrode portion 300a of the electrode unit 31 are shorter than the lengths of the first electrodes 300-1 and the second electrodes 300-2 of the electrode portion 300a and the electrode portion 300c of the electrode unit 32.

### Modified Example 3

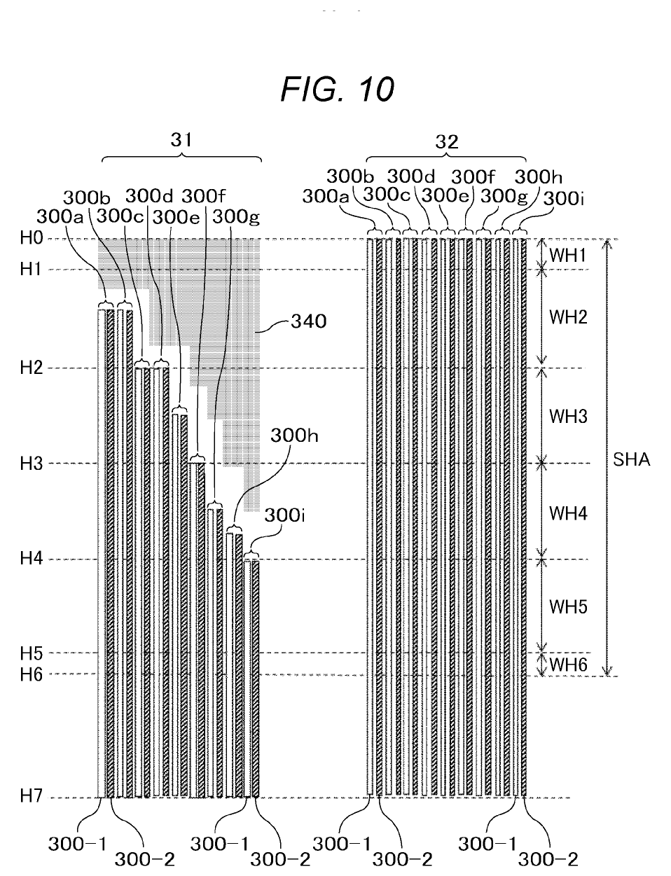

Electrodes used for the electrode units 31 and 32 in a modified example 3 of the embodiment will be described with reference to FIG. 10. In the modified example 3, the electrode length of the electrode portion is different from that of the embodiment, and a conductor is provided at a position where no electrode of the electrode unit 31 is provided. Other configurations of the modified example 3 are similar to those of the embodiment. Also in the modified example 3, effects can be obtained similar to those in the above-described embodiment.

The heights of the upper ends of the first electrode 300-1 and the second electrode 300-2 of each of a first electrode portion 300a and a second electrode portion 300b of the electrode unit 31 are lower than H1 and higher than H2. The heights of the upper ends of the first electrode 300-1 and the second electrode 300-2 of each of a third electrode portion 300c and a fourth electrode portion 300d of the electrode unit 31 are the height of H2.

The heights of the upper ends of the first electrode 300-1 and the second electrode 300-2 of a fifth electrode portion 300e of the electrode unit 31 are lower than the height of H2 and higher than the height of H3. The heights of the upper ends of the first electrode 300-1 and the second electrode 300-2 of a sixth electrode portion 300f of the electrode unit 31 are the heights of H3. The heights of the upper ends of the first electrode 300-1 and the second electrode 300-2 of a seventh electrode portion 300g of the electrode unit 31 are lower than the height of H3 and higher than the height of H4. The heights of the upper ends of the first electrode 300-1 and the second electrode 300-2 of an eighth electrode portion 300h of the electrode unit 31 are lower than the heights of the first electrode 300-1 and the second electrode 300-2 of the seventh electrode portion 300g and higher than the height of H4. The heights of the upper ends of the first electrode 300-1 and the second electrode 300-2 of a ninth electrode portion 300i of the electrode unit 31 are the height of H4.

The electrode unit 31 has a shape in which the upper portions of the first electrode 300-1 and the second electrode 300-2 are removed from the electrode portions 300a to 300i of the electrode unit 32. A conductor 340 connected to the reference potential (for example, earth) is installed at a position (that is, the space from which the electrodes are removed) where the upper portions of the first electrode 300-1 and the second electrode 300-2 are removed, at a distance not discharging from the first electrode 300-1 and the second electrode 300-2. This makes it possible to reduce the influence of an unstable electromagnetic field in the space from which the electrodes are removed.

In the above, the embodiment of the present disclosure has been specifically described. However, the present disclosure is not limited to the embodiments described above, and thus can be variously modified without departing from the gist of the present disclosure.

In addition, for example, in the above-described embodiments, an example has been described in which the reactant is supplied after the source is supplied. The present disclosure is not limited to such an embodiment, and the order of supplying the source and the reactant may be reversed. That is, the source may be supplied after the reactant is supplied. By changing the supplying order, it is possible to change film quality or a composition ratio of a film to be formed.

The present disclosure is suitably applicable not only to the case of forming a SiO film or a SiN film on the wafer 200, but also to the case of forming a Si-based oxide film such as a silicon oxycarbide film (SiOC film), a silicon oxycarbonitride film (SiOCN film), or a silicon oxynitride film (SiON film) on the wafer 200.

It is preferable that the recipe used in the film-forming processing is individually prepared in accordance with the processing contents, and is stored in the memory 121c through a telecommunication line or the external memory 123. When various processing is started, it is preferable that the CPU 121a suitably selects an appropriate recipe from a plurality of recipes stored in the memory 121c, in accordance with the processing contents. As a result, thin films with various film types, composition ratios, film qualities, and thicknesses of the films can be generally and reproducibly formed by one substrate processing apparatus. In addition, it is possible to reduce a burden on an operator, and it is possible to quickly start various processing while avoiding an operation error.

The above-described recipe is not limited to a newly created recipe and thus may be prepared, for example, by changing an existing recipe installed in advance in the substrate processing apparatus. When changing the recipe, the changed recipe may be installed in the substrate processing apparatus through a telecommunication line or a recording medium in which the recipe has been recorded. The existing recipe already installed in the substrate processing apparatus may be directly changed by operation of the inputter/outputter 122 included in the existing substrate processing apparatus.

In the above-described embodiment, an example has been described in which a film is formed by use of a batch-type substrate processing apparatus that processes a plurality of substrates at a time. The present disclosure is not limited to the above-described embodiment, and is suitably applicable to a case where a film is formed by use of a single wafer type substrate processing apparatus that processes one or more substrates at a time, for example. In the above-described embodiment, an example has been described in which a film is formed by use of a substrate processing apparatus including a hot wall type processing furnace. The present disclosure is not limited to the above-described embodiment, and is suitably applicable to a case where a film is formed by use of a substrate processing apparatus including a cold wall type processing furnace.

Also in cases where such substrate processing apparatuses are used, each piece of processing can be performed in accordance with processing procedures and processing conditions similar to those in the above-described embodiment and modified examples, so that effects can be obtained similar to those in the above-described embodiment and modified examples.

The above-described embodiment and modified examples can be used in combination as appropriate. Processing procedures and processing conditions at this time can be similar to, for example, the processing procedures and processing conditions in the embodiment and modified examples described above.

According to the present disclosure, it is possible to perform more uniform substrate processing.

What is claimed is:

1. A substrate processing apparatus comprising: a process chamber configured to process a substrate; and a first electrode unit including: a first electrode portion including one of a plurality of first electrodes to which high frequency power is applied, and one of a plurality of second electrodes to which a reference potential is applied, the one of the plurality of first electrodes and the one of the plurality of second electrodes included in the first electrode portion having equal lengths; a second electrode portion including one of the plurality of first electrode and one of the plurality of second electrodes, the one of the plurality of first electrodes and the one of the plurality of second electrodes included in the second electrode portion having different lengths from those of the one of the plurality of first electrodes and the one of the plurality of second electrodes, included in the first electrode portion; and a third electrode portion including one of the plurality of first electrodes and one of the plurality of second electrodes, the one of the plurality of first electrodes and the one of the plurality of second electrodes included in the third electrode portion having different lengths from those of the one of the plurality of first electrodes and the one of the plurality of second electrodes included in the first electrode portion and the one of the plurality of first electrodes and the one of the plurality of second electrodes included in the second electrode portion.

2. The substrate processing apparatus according to claim 1, wherein the number of the plurality of first electrodes included in the first electrode portion is equal to the number of the plurality of second electrodes included in the first electrode portion.

3. The substrate processing apparatus according to claim 1, wherein the number of the plurality of first electrodes included in the first electrode portion is different from the number of the plurality of second electrodes included in the first electrode portion.

4. The substrate processing apparatus according to claim 3, wherein two or more of the plurality of the first electrodes are provided in the first electrode portion.

5. The substrate processing apparatus according to claim 4, wherein the two or more of the plurality of first electrodes are continuously arranged.

6. The substrate processing apparatus according to claim 1, wherein lengths of the one of a plurality of first electrodes and the one of a plurality of second electrodes of the first electrode portion are longer than lengths of the first one of a plurality of electrodes and the one of a plurality of second electrodes of the second electrode portion and lengths of the one of a plurality of first electrodes and the one of a plurality of second electrodes of the third electrode portion.

7. The substrate processing apparatus according to claim 1, wherein lengths of the one of a plurality of first electrodes and the one of a plurality of second electrodes of the second electrode portion are shorter than lengths of the one of a plurality of first electrodes and the one of a plurality of second electrodes of the first electrode portion and longer than lengths of the one of a plurality of first electrodes and the one of a plurality of second electrodes of the third electrode portion.

8. The substrate processing apparatus according to claim 1, wherein lengths of the one of a plurality of first electrodes and the one of a plurality of second electrodes of the third electrode portion are shorter than lengths of the one of a plurality of first electrodes and the one of a plurality of second electrodes of the first electrode portion and the one of a plurality of first electrodes and the one of a plurality of second electrodes of the second electrode portion.

9. The substrate processing apparatus according to claim 1, wherein the first electrode portion, the second electrode portion, and the third electrode portion are arranged in that order.

10. The substrate processing apparatus according to claim 1, comprising a second electrode unit including: a fourth electrode portion including one of a plurality of first electrodes to which high frequency power is applied, and one of a plurality of second electrodes to which a reference potential is applied, the one of the plurality of first electrodes and the one of the plurality of second electrodes included in the fourth electrode portion having equal lengths; and a fifth electrode portion including one of the plurality of first electrodes and one of the plurality of second electrodes having lengths equal to those of the one of the plurality of first electrodes and the one of the plurality of second electrodes of the fourth electrode portion.

11. The substrate processing apparatus according to claim 1, comprising a second electrode unit including: a fourth electrode portion including one of a plurality of first electrodes to which high frequency power is applied, and one of a plurality of second electrodes to which a reference potential is applied, the one of the plurality of first electrodes and the one of the plurality of second electrodes included in the fourth electrode portion having equal lengths; and a fifth electrode portion including one of the plurality of first electrodes and one of the plurality of second electrodes having lengths different from those of the one of the plurality of first electrodes and the one of the plurality of second electrodes of the fourth electrode portion.

12. The substrate processing apparatus according to claim 10, wherein the number of the plurality of first electrodes included in the fourth electrode portion is equal to the number of the plurality of second electrodes included in the fourth electrode portion.

13. The substrate processing apparatus according to claim 10, wherein the number of the plurality of first electrodes included in the fourth electrode portion is different from the number of the plurality of second electrodes included in the fourth electrode portion.

14. The substrate processing apparatus according to claim 1, wherein the first electrode unit is disposed outside the process chamber.

15. The substrate processing apparatus according to claim 12, wherein lengths of the one of a plurality of first electrodes and the one of a plurality of second electrodes of the first electrode portion are shorter than lengths of the one of a plurality of first electrodes and the one of a plurality of second electrodes of the fourth electrode portion.

16. The substrate processing apparatus according to claim 13, wherein lengths of the one of a plurality of first electrodes and the one of a plurality of second electrodes of the first electrode portion are shorter than lengths of the one of a plurality of first electrodes and the one of a plurality of second electrodes of the fourth electrode portion and the one of a plurality of first electrodes and the one of a plurality of second electrodes of the fifth electrode portion.

17. A plasma generating device comprising: a first electrode unit including: a first electrode portion including one of a plurality of first electrodes to which high frequency power is applied, and one of a plurality of second electrodes to which a reference potential is applied, the one of a plurality of first electrodes and the one of a plurality of second electrodes included in the first electrode portion having equal lengths; a second electrode portion including one of the plurality of first electrodes and one of the plurality of second electrodes, the one of the plurality of first electrodes and the one of the plurality of second electrodes included in the second electrode portion having different lengths from those of the one of the plurality of first electrodes and the one of the plurality of second electrodes included in the first electrode portion; and a third electrode portion including one of the plurality of first electrodes and one of the plurality of second electrodes, the one of the plurality of first electrodes and the one of the plurality of second electrodes included in the third electrode portion having different lengths from those of the one of the plurality of first electrodes and the one of the plurality of second electrodes included in the first electrode portion and the one of the plurality of first electrodes and the one of the plurality of second electrodes included in the second electrode portion.

18. A method of processing a substrate comprising: carrying a substrate in a process chamber; and generating a plasma by a first electrode unit including: a first electrode portion including one of a plurality of first electrodes to which high frequency power is applied, and one of a plurality of second electrodes to which a reference potential is applied, the one of the plurality of first electrodes and the one of the plurality of second electrodes having equal lengths; a second electrode portion including one of the plurality of first electrodes and one of the plurality of second electrodes, the one of the plurality of first electrodes and the one of the plurality of second electrodes included in the second electrode portion having different lengths from those of the one of the plurality of first electrodes and the one of the plurality of second electrodes included in the first electrode portion; and a third electrode portion including one of the plurality of first electrodes and one of the plurality of second electrodes, the one of the plurality of first electrodes and the one of the plurality of second electrodes included in the third electrode portion having different lengths from those of the one of the plurality of first electrodes and the one of the plurality of second electrodes included in the first electrode portion and the one of the plurality of first electrodes and the one of the plurality of second electrodes included in the second electrode portion.

19. A method of manufacturing a semiconductor device, including the method of processing a substrate according to claim 18.

20. A non-transitory computer-readable recording medium recording a program for causing a substrate processing apparatus to execute the method of processing a substrate according to claim 18.
